(19) United States
(12) Patent Application Publication
(10) Pub. No.: US 2026/0186106 A1
(43) Pub. Date: Jul. 2, 2026

(54) OPTIMIZATION OF THE LiDAR LASER CHARGING AND EMISSION CIRCUIT

(71) Applicant: Y.E. Hub Armenia LLC, Yerevan (AM)

(72) Inventor: Oleg LEONIDOV, Moscow (RU)

(21) Appl. No.: 19/426,060

(22) Filed: Dec. 19, 2025

(30) Foreign Application Priority Data
Dec. 28, 2024 (RU) 2024140302

(51) Int. Cl. G01S 7/484; G01S 7/481; G01S 17/10; H03K 4/02

(52) U.S. Cl. CPC G01S 7/484; G01S 7/4815; H03K 4/023; G01S 17/10

(57) ABSTRACT

The light source circuit of the LIDAR system includes four capacitors, four laser diodes, two charging circuit, four switches, and two drivers. The first driver is configured discharge the first capacitor through the first laser diode by engaging the first switch, and the third capacitor through the third laser diode by engaging the third switch. The second driver is configured to discharge the second capacitor through the second laser diode by engaging the second switch, and the fourth capacitor through the fourth laser diode by engaging the fourth switch. The disclosed light source circuit allows to charge two or more capacitors at once and discharge the capacitors through their respective laser diodes in sequence.

### CROSS-REFERENCE

The present application claims priority to Russian Patent Application No. 2024140302, entitled “Optimization of the Lidar Laser Charging and Emission Circuit”, filed Dec. 28, 2024, the entirety of which is incorporated herein by reference.

### TECHNICAL FIELD

The present technology generally pertains to systems, devices, and methods to support LIDAR sensing and, in particular, to a circuit of the light source of the LIDAR system and to a method to operate the circuit.

### BACKGROUND

A light detection and ranging (LIDAR) system is a system that scans space using light beams. FIG. 1 illustrates a block diagram of a LIDAR system in accordance with some non-limiting embodiments. LIDAR system 100 consists of emitter 110 and receiver 120 of light pulses. Emitter 110 includes light source 112 (for example, a laser). Light source 112 emits short light pulses 141 to surrounding object 140. Receiver 120 receives reflected light signal 142. By knowing the speed of light and determining the response time of light signals from objects, LIDAR can determine the distance to the object.

LIDAR systems may use various emitters, scanners and photodetectors (receiving units). For example, emitter 110 besides light source 112 also includes scanner 111, and driver 113. Receiver 120 includes optical components 121, light detector 122, and electronic device 123. Electronic device 123 is configured to receive and process signals from light detector 122. Signal processing may include amplifying, attenuating, differentiating, filtering, comparing, storing or otherwise handling electric signals. For these purposes, electronic device 123 may comprise an application-specific circuit. Electronics device 123 may be controlled by controlling device 130 which may include a processor. Controlling device 130 may also control driver 113 for light source 112 and scanner 111. Light detector 122 may include a silicon photomultiplier (SiPM) sensor.

A number of features should be considered when designing lidars. Short laser pulses are required to measure with high accuracy a distance (a range) to an object using the time-of-flight method (that is, when the laser emits/shoots, and the receiver receives without additional calculations). Therefore, it is necessary to concentrate energy as much as possible at the initial stage in order to measure the range more accurately.

Electronic components of light source 112 of LIDAR emitter 110 may impose limitations on LIDAR system 100 performance. In order to emit the shortest possible pulses (for example, about 1 ns), it is necessary to have fast electronic components (ADC, drivers, etc.). However, the shorter the emitted pulse, the greater the parasitic inductance, which may interfere with correct operation of light source 112. There are some compromises available while selecting the duration of the emitted pulse, which make it relatively short and acceptable for subsequent processing.

Switches may be used to generate short pulses of electric current. These switches may switch on and off quickly (for example, at about 400 ps). The switches may be gallium nitride (GaN) transistors, rather than silicon transistors. GaN transistors are able to open and close quickly facilitating short laser pulses generation. GaN transistors are more efficient than silicon transistors and can operate at higher voltages and frequencies. This may provide lower heat transfer.

Designing LIDAR system 100, for example, light source 112 of emitter 110, may require to use specialized boards and specialized (faster) electronic components. However, faster components may have larger dimensions consuming expensive “real estate” space on the specialized circuit boards. These faster components may dissipate larger amount of heat (per unit of time), and they may cost more, which may prevent application of these faster components in light source 112 of emitter 110.

Therefore, improvements in the light source circuit of the emitter of the LIDAR system and the methods of its are desirable.

US Patent Application Publication 2024/0215169 A1 discloses a LIDAR device charging circuit that includes a plurality of energy storage devices. The lidar device also includes a pulser circuit. The charging circuit is configured to receive an indication of a first set of light emitters to be fired during a firing cycle. The charging circuit is configured to selectively charge, during a charging cycle, a first set of energy storage devices. The first set of energy storage devices is a subset of the plurality of energy storage devices.

### SUMMARY

An aspect of the disclosed invention is a specific electric circuit to support charging of each capacitor and discharging each capacitor through a respective laser diode. The disclosed electric circuit may allow to charge two or more capacitors at once and discharge the capacitors through their respective laser diodes in sequence.

According to embodiments of the present disclosure, there is provided a LIDAR system. The LIDAR system includes an emitting unit, the emitting unit is configured to emit a light onto surrounding objects, and a receiving unit, the receiving unit is configured to detect a portion of the light reflected from the surrounding objects. In some embodiments the emitting unit includes a sub-system. The sub-system includes a first capacitor, a second capacitor, and a first charging circuit configured to place a first charge and a second charge into the first and the second capacitor respectively. The sub-system further includes a third capacitor, a fourth capacitor, and a second charging circuit configured to place a third charge and a fourth charge into the third and the fourth capacitor respectively. The sub-system further includes a first light emitting diode (LED), a second LED, a third LED, a fourth LED, a first driver configured to remove the first charge from the first capacitor through the first LED and the third charge from the third capacitor through the third LED; and a second driver configured to remove the second charge from the second capacitor through the second LED and the fourth charge from the fourth capacitor through the fourth LED. Moving the first, the second, the third, and the fourth charge through a respective LED causes the respective LED to emit light. In some embodiments the sub-system being configured to operate the first charging circuit to charge the first and the second capacitor, and maintain the third and the fourth capacitor void of charge. The sub-system being further configured to operate the first driver to discharge the first and the third capacitor, and operate the second driver to discharge the second and the fourth capacitor. In some embodiments, the sub-system is being configured to operate the second charging circuit to charge the third and the fourth capacitor, maintain the first and the second capacitor void of charge, operate the first driver to discharge the first and the third capacitor, and operate the second driver to discharge the second and the fourth capacitor.

In some embodiments, the LIDAR system may further comprise an electric circuit, the electric circuit being configured to coordinate operations of the first and the second drivers of the sub-system with operations of drivers of other sub-systems of the LIDAR system. In some other embodiments, the emitting unit of the LIDAR system includes one or more other sub-systems. In some embodiments of the LIDAR system, the first driver is configured to remove the first charge from the first capacitor through the first LED by engaging a first switch and to remove the third charge from the third capacitor through the third LED by engaging a third switch; the second driver is configured to remove the second charge from the second capacitor through the second LED by engaging a second switch, and to remove the fourth charge from the fourth capacitor through the fourth LED by engaging a fourth switch. In some embodiments of the LIDAR system, the first LED is adjacent to the third LED and the second LED is adjacent to the fourth LED. In some other embodiments of the LIDAR system, each LED is a vertical cavity surface emitting laser diode or an edge emitting laser diode.

According to embodiments of the present disclosure, there is provided a method to operate the sub-system of the LIDAR system. The sub-system includes a first capacitor, a second capacitor, a third capacitor, a fourth capacitor, a first light emitting diode (LED), a second LED, a third LED, a fourth LED, a first driver, configured to discharge the first capacitor and the third capacitor through the first LED and the third LED respectively, and a second driver, configured to discharge the second capacitor and the fourth capacitor through the second LED and the fourth LED respectively. The method to operate the sub-system comprises: operating a first charging circuit to place a first and a second charge to the first and the second capacitor respectively, and maintaining the third and the fourth capacitor void of charge. The method may further comprise: operating the first driver to discharge the first and the third capacitor through the first LED and the third LED respectively, thereby moving the first charge through the first LED and causing only the first LED to emit light, and operating the second driver to discharge the second and the fourth capacitor through the second LED and the fourth LED respectively, thereby moving the second charge through the second LED and causing only the second LED to emit light. In some embodiments, the method may further comprise: maintaining the first and the second capacitor void of charge, operating a second charging circuit to place a third and a fourth charge to the third and the fourth capacitor respectively, operating the first driver to discharge the first and the third capacitor through the first LED and the third LED respectively, thereby moving the third charge through the third LED and causing only the third LED to emit light, and operating the second driver to discharge the second and the fourth capacitor through the second LED and the fourth LED respectively, thereby moving the fourth charge through the fourth LED and causing only the fourth LED to emit light. In some embodiments, the method further comprises: coordinating operations of the first and the second driver with operations of other drivers of the LiDAR system. In some other embodiments, the method wherein the other drivers of the LiDAR system include one or more pairs of drivers.

In some embodiments of the method, the first driver removes the first charge from the first capacitor through the first LED by engaging a first switch, the first driver also removes the third charge from the third capacitor through the third LED by engaging a third switch. The second driver removes the second charge from the second capacitor through the second LED by engaging a second switch, and the second driver also removes the fourth charge from the fourth capacitor through the fourth LED by engaging a fourth switch. In some embodiments of the method, the first LED is adjacent to the third LED and the second LED is adjacent to the fourth LED. In some other embodiments of the method, each LED being a vertical cavity surface emitting laser diode or an edge emitting laser diode.

In some embodiments of the method to operate the sub-system of the LIDAR system the first and the second charging circuit being operated during a first period of time and a second period of time respectively, a value of the first charge and a value of the second charge being defined by the first period of time, and a value of the third charge and a value of the fourth charge being defined by the second period of time.

According to embodiments of the present disclosure, there is provided a subsystem of the LIDAR system. The sub-system comprising: a first capacitor, a second capacitor, and a first charging circuit configured to place a first charge and a second charge into the first and the second capacitor respectively. The sub-system further comprising: a third capacitor, a fourth capacitor, and a second charging circuit configured to place a third charge and a fourth charge into the third and the fourth capacitor respectively. The sub-system may also include a first light emitting diode (LED), a second LED, a third LED, a fourth LED, a first driver configured to remove the first charge from the first capacitor through the first LED and the third charge from the third capacitor through the third LED, and a second driver configured to remove the second charge from the second capacitor through the second LED and the fourth charge from the fourth capacitor through the fourth LED. Moving the first, the second, the third, and the fourth charge through a respective LED causes the respective LED to emit light. In some embodiments, the sub-system being configured to: operate the first charging circuit to charge the first and the second capacitor, maintain the third and the fourth capacitor void of charge, operate the first driver to discharge the first and the third capacitor, operate the second driver to discharge the second and the fourth capacitor, operate the second charging circuit to charge the third and the fourth capacitor, maintain the first and the second capacitor void of charge, operate the first driver to discharge the first and the third capacitor, and operate the second driver to discharge the second and the fourth capacitor.

In some embodiments of the sub-system of the LIDAR system, the LiDAR system includes an electric circuit, the electric circuit being configured to coordinate operations of the first and the second drivers of the sub-system with operations of drivers of other sub-systems of the LIDAR system, and/or the LIDAR system includes one or more other sub-systems. In some embodiments of the sub-system, the first driver is configured to remove the first charge from the first capacitor through the first LED by engaging a first switch, the first driver is also configured to remove the third charge from the third capacitor through the third LED by engaging a third switch, the second driver is configured to remove the second charge from the second capacitor through the second LED by engaging a second switch, and the second driver is also configured to remove the fourth charge from the fourth capacitor through the fourth LED by engaging a fourth switch. In some embodiments of the sub-system, the first LED is adjacent to the third LED and the second LED is adjacent to the fourth LED. In some other embodiments of the sub-system, each LED is a vertical cavity surface emitting laser diode or an edge emitting laser diode. In some embodiments, each switch is a gallium nitride filed effect transistor.

It should be expressly understood that the terms related to the spatial orientation listed above should be interpreted, in the context of the present specification, as depicted in the provided drawings.

The embodiments have been described above in conjunctions with aspects of the present invention upon which they can be implemented. Those skilled in the art will appreciate that embodiments may be implemented in conjunction with the aspect with which they are described, but may also be implemented with other embodiments of that aspect. When embodiments are mutually exclusive, or are otherwise incompatible with each other, it will be apparent to those skilled in the art. Some embodiments may be described in relation to one aspect, but may also be applicable to other aspects, as will be apparent to those of skill in the art.

### BRIEF DESCRIPTION OF THE DRAWINGS

Further features and advantages of the present invention will become apparent from the following detailed description, taken in combination with the appended drawings, in which:

FIG. 1 illustrates a block diagram of a LIDAR system in accordance with some non-limiting embodiments.

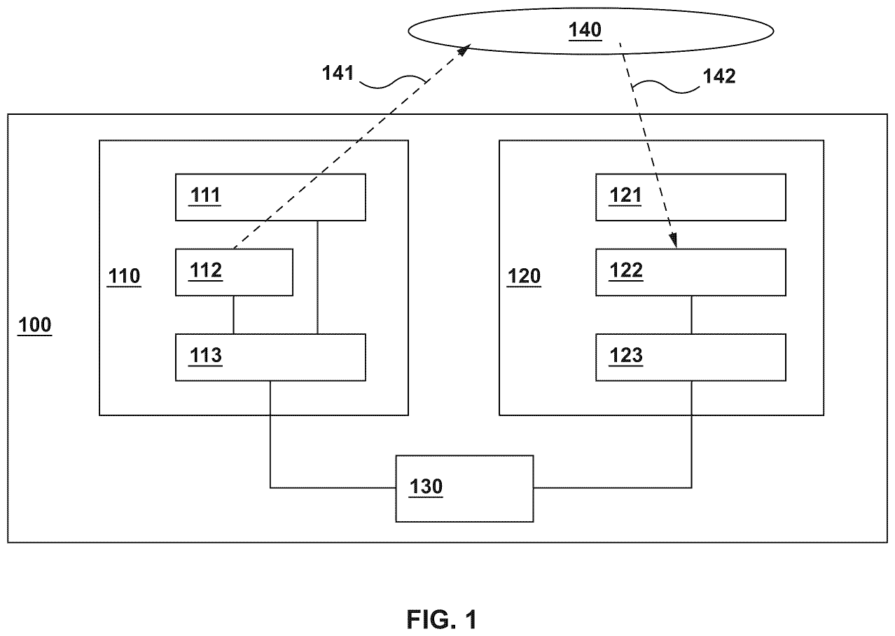

FIG. 2 illustrates a circuit of a light source according to some non-limiting embodiments of the disclosed technology.

FIG. 3 illustrates a circuit of a light source according to some non-limiting embodiments.

FIG. 4 illustrates a flowchart of a method to operate the circuit of the light source according to some non-limiting embodiments.

FIG. 5 illustrates a circuit of a light source according to some other non-limiting embodiments.

FIG. 6 illustrates a flowchart of a method of operation the circuit of the light source according to some non-limiting embodiments.

FIG. 7 illustrates an example of mutual arrangement of the circuit elements on the surface of the printed circuit board according to some non-limiting embodiments.

### DETAILED DESCRIPTION

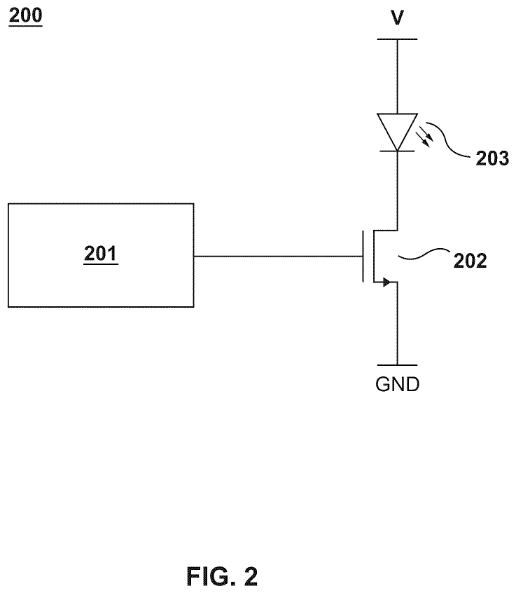

FIG. 2 illustrates circuit 200 of light source 112 according to some non-limiting embodiments of the disclosed technology. Driver 201 controls a switch, implemented herein as transistor 202. Transistor 202 may be, for example, a GaN transistor, switching on and off laser diode 203.

LiDAR system 100 may be a multi-channel LIDAR system and may require light source 112 with more than one laser diode. For example, light source 112 may have 64 laser diodes. To operate these 64 laser diodes, 64 drivers may be required - one driver for each laser diode. However, 64 drivers may take a lot of space on the circuit board and may require complex tracing. At the same time, the circuit board of light source 112 may have dimensional constraints imposed by a particular embodiment of LIDAR system 100. Application of fewer drivers in multi-channel light source 112 may help not only to maintain desired dimensions of the circuit board, but may also help to reduce the total cost of the circuit's components, reduce complexity of tracing on the circuit board, and provide fine-tuning (a specific configuration) of the emitted light energy by streamlining the arrangement of the components on the circuit board to ensure, for example, energy regulations for laser emission.

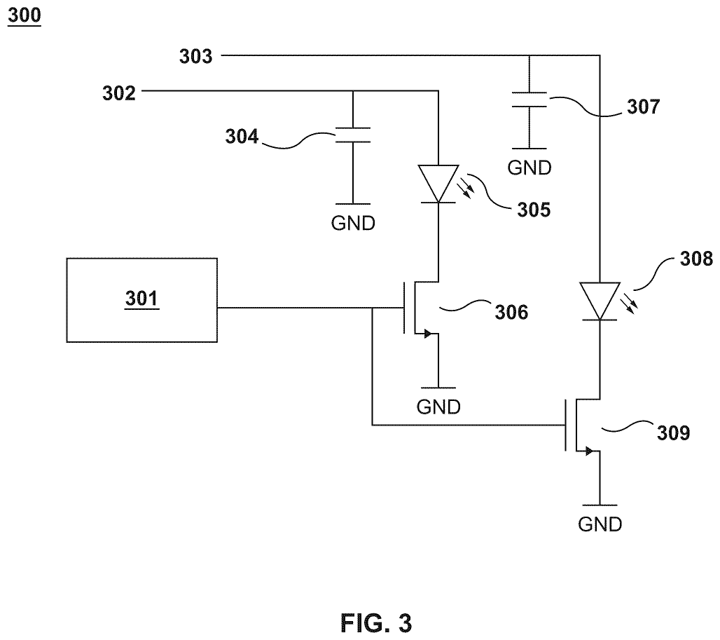

FIG. 3 illustrates circuit 300 of light source 112 according to some non-limiting embodiments. Circuit 300 includes two transistors (306 and 309) connecting cathodes of laser diodes 305 and 308 to the ground. The gates of transistors 306 and 309 are connected. Driver 301 operates the gates of transistors 306 and 309 and, therefore, controls electric current through laser diodes 305 and 308. Anodes of laser diodes 305 and 308 are connected capacitors 304 and 307 respectively. Anodes of laser diodes 305 and 308 are also connected to charge anodes 302 and charge anode 303 respectively. In this embodiment, emitter 112 may discharge laser diodes 305 and 308 in sequence and not at once. Charge anodes 302 and 303 of a charge injection circuit are activated (a control signal is received) during a respective period of time, the voltage feeds capacitors 304 and 307, then the charge injection circuit disactivates charge anodes 302 and 303. The longer time when charge anodes 302 and 303 are activated, the larger charge is accumulated on capacitors 304 and 307. It is possible, for example, to charge capacitors 304 and 307 completely or partially, and, consequently, opportunity to regulate the power of light emission, that is, the energy in the pulse.

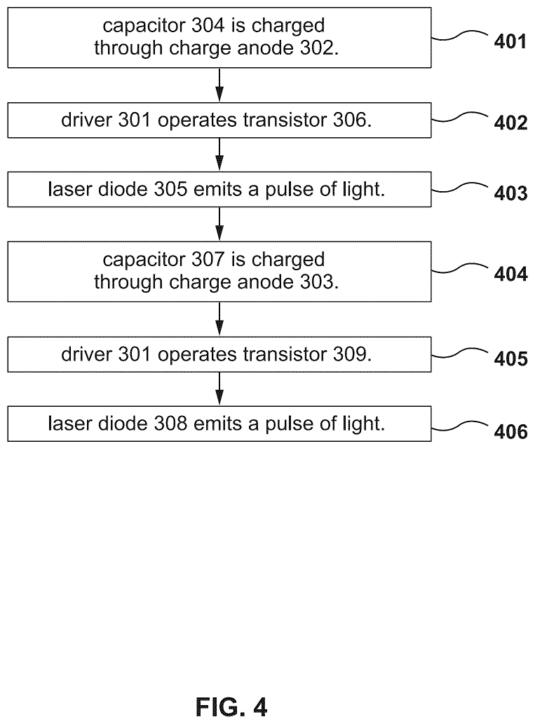

FIG. 4 illustrates a flowchart of a method to operate circuit 300 of light source 112 according to some non-limiting embodiments. At action 401, capacitor 304 is charged. A voltage is applied to capacitor 304 through charge anode 302 and a charge is accumulated on capacitor 304. At action 402, driver 301 operates the gate of transistor 306 to open it. At action 403, transistor 306 switches on, and a sharp electric current pulse passes through laser diode 305. The entire accumulated charge of capacitor 304 or a portion of this charge flows through laser diode 305 to the ground. As a result, laser diode 305 emits a pulse of light. Then, at action 404, capacitor 307 is charged. A voltage is applied to capacitor 307 through charge anode 303. At action 405, driver 301 operates transistor 309. At action 406, transistor 309 switches on and capacitor 307 discharges its charge (or a portion of the charge) through laser diode 308. Diode laser 308 emits a short pulse of light.

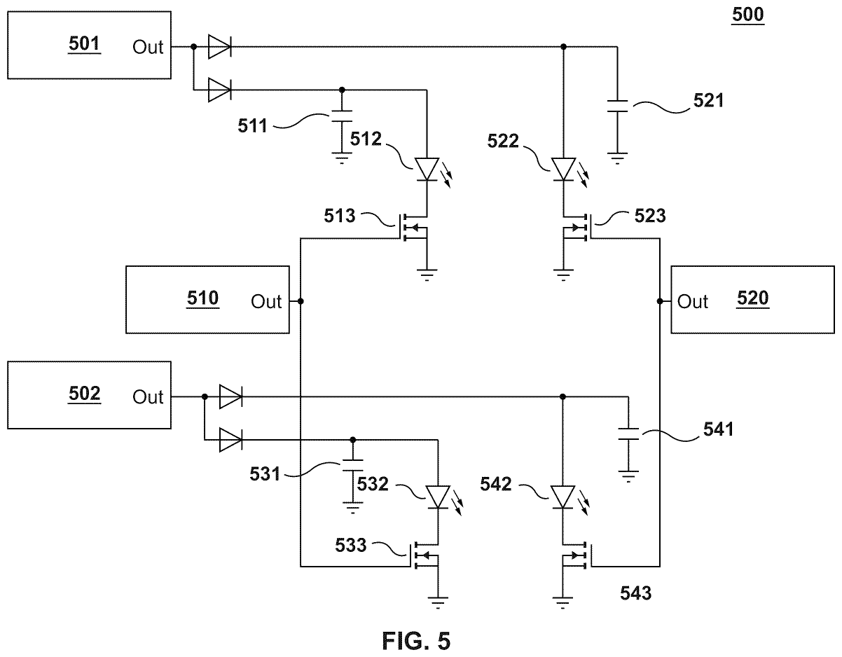

FIG. 5 illustrates circuit 500 of light source 112 according to some other non-limiting embodiments. Circuit 500 includes capacitor 511, capacitor 521, and charging circuit 501, configured to place a first charge and a second charge into capacitors 511 and 521. Circuit 500 further includes capacitor 531, capacitor 541, and charging circuit 502. Charging circuit 502 is configured to place a third charge and a fourth charge into capacitor 531 and 541, respectively. Circuit 500 includes two drivers (510 and 520) and four laser diodes: 512, 522, 532, and 542. Driver 510 is configured to remove the first charge from capacitor 511 through laser diode 512 and the third charge from capacitor 531 through laser diode 532. Driver 520 is configured to remove the second charge from capacitor 521 through laser diode 522 and the fourth charge from capacitor 541 through laser diode 542. Moving the first, the second, the third, and the fourth charge through a respective laser diode (512, 522, 532, and 542) causes the respective laser diode to emit light.

Circuit 500 also includes four transistors: 513, 523, 533, and 543. Driver 510 is configured to remove the first charge from capacitor 511 through laser diode 512 by engaging transistor 513. Driver 510 is also configured to remove the third charge from capacitor 531 through laser diode 532 by engaging transistor 533. Driver 520 is configured to remove the second charge from capacitor 521 through laser diode 522 by engaging transistor 523. Driver 520 is also configured to remove the fourth charge from capacitor 541 through laser diode 542 by engaging transistor 543.

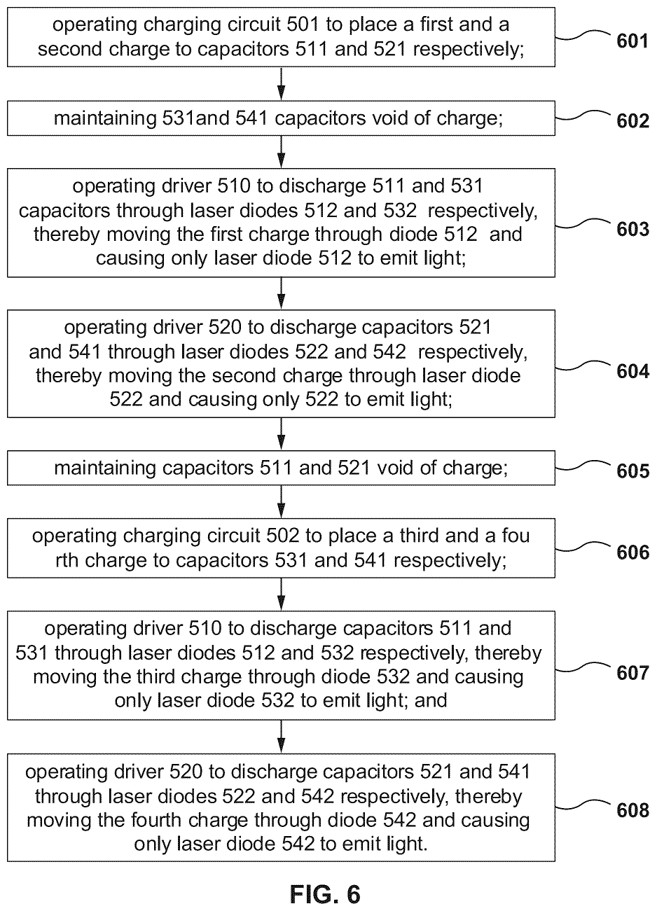

FIG. 6 illustrates a method of operation of circuit 500. At action 601, operating charging circuit 501 to place a first and a second charge to capacitors 511 and 521 respectively. At action 602, maintaining 531 and 541 capacitors void of charge. At action 603, operating driver 510 to opens transistors 513 and 533 to discharge 511 and 531 capacitors through laser diodes 512 and 532 respectively. Moving the first charge through laser diode 512 is causing laser diode 512 to emit light. As only laser diode 512 has a charge on capacitor 511, only laser diode 512 emits light. Laser diode 532 does not emit because capacitor 531 has not been charged.

At action 604, operating driver 520 to open transistors 523 and 543 to discharge capacitors 521 and 541 through laser diodes 522 and 542 respectively. Moving the second charge through laser diode 522 causes laser diode 522 to emit light. Laser diode 542 does not emit light because capacitor 541 hasn't been charged.

At action 605, maintaining capacitors 511 and 521 void of charge. At action 606, operating charging circuit 502 to place a third and a fourth charge to capacitors 531 and 541 respectively. At action 607, operating driver 510 to open transistors 513 and 533 to discharge capacitors 511 and 531 through laser diodes 512 and 532 respectively. Moving the third charge through diode 532 causes laser diode 532 to emit light. Laser diode 512 does not emit light, as capacitor 511 is void of charge.

At action 608, operating driver 520 to open transistors 523 and 543 to discharge capacitors 521 and 541 through laser diodes 522 and 542 respectively. Moving the fourth charge through laser diode 542 causes laser diode 542 to emit light. Laser diode 522 does not emit light, as capacitor 521 is void of charge.

In some embodiments, drivers 510 and 520 coordinate their operations with operations of other drivers of LIDAR system 100.

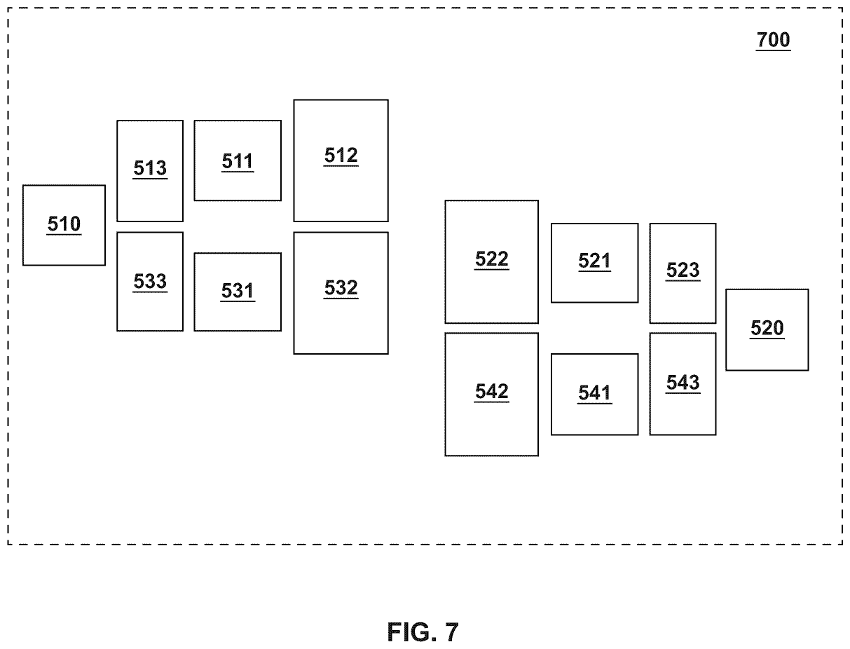

FIG. 7 illustrates an example of mutual arrangement of the elements-capacitors, transistors, laser diodes, and drivers-of circuit 500 on the surface of printed circuit board 700 according to some non-limiting embodiments. (FIG. 7 does not show the respective tracing of the elements and charging circuits 501 and 502.) In this example, transistor 513 is adjacent to transistor 533, and laser diode 512 is adjacent to laser diode 532. Transistor 523 is adjacent to transistor 543, and laser diode 522 is adjacent to laser

### Diode 542.

In some embodiments, light source 112 of emitter 110 may contain several lasers (for example, 64 laser diodes) and several drivers (for example, 32 drivers). Each driver (D1, D2, . . . , D32) is connected to a respective couple of lasers (L1 and L2; L3 and L4; . . . ; L63 and L64) arranged sequentially in lines and column. Light source 112 may also include several capacitors (for example, 64 capacitors) arranged in adjacent lines or columns. Two adjacent capacitors (C1 and C3; C2 and C4; . . . ) located, for example, on the same horizontal line may be charged simultaneously. Only lasers connected to charged capacitors may emit light. Each laser, connected to a charged capacitor, emits light in accordance with a signal from a respective driver. In some embodiments of light source 112 operation, at every point in time only one laser may emit light. By optimizing the charge and radiation circuit, it may be possible to halve the number of drivers (32 instead of 64) on the circuit board, to reduce the size of the circuit board, to reduce the total cost of necessary components, and to simplify the installation/tracing process.

It should be noted that, in some embodiments of the present technology, the processor of controlling device 130 may comprise one or more processors and/or one or more microcontrollers configured to execute instructions and to carry out operations associated with the operation of LIDAR system 100. In various non-limiting embodiments of the present technology, the processor may be implemented as a single-chip, multiple chips and/or other electrical components including one or more integrated circuits and printed circuit boards. The processor may optionally contain a cache memory unit for temporary local storage of instructions, data, or additional computer information. By way of example, the processor may include one or more processors, or one or more controllers dedicated for certain processing tasks.

Moreover, explicit use of the term “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read-only memory (ROM) for storing software, random access memory (RAM), and non-volatile storage.

Although the present invention has been described with reference to specific features and embodiments thereof, it is evident that various modifications and combinations can be made thereto without departing from the invention. The specification and drawings are, accordingly, to be regarded simply as an illustration of the invention as defined by the appended claims, and are contemplated to cover any and all modifications, variations, combinations or equivalents that fall within the scope of the present invention.

What is claimed is:

1. A sub-system of a light detection and ranging (LiDAR) system, the sub-system comprising:
a first capacitor, a second capacitor, a first charging circuit configured to place a first charge and a second charge into the first and the second capacitor respectively,
a third capacitor, a fourth capacitor, a second charging circuit configured to place a third charge and a fourth charge into the third and the fourth capacitor respectively,
a first light emitting diode (LED), a second LED, a third LED, a fourth LED,
a first driver configured to remove the first charge from the first capacitor through the first LED and the third charge from the third capacitor through the third LED, and
a second driver configured to remove the second charge from the second capacitor through the second LED and the fourth charge from the fourth capacitor through the fourth LED, moving the first, the second, the third, and the fourth charge through a respective LED causes the respective LED to emit light,
the sub-system being configured to:
operate the first charging circuit to charge the first and the second capacitor;
maintain the third and the fourth capacitor void of charge;
operate the first driver to discharge the first and the third capacitor;
operate the second driver to discharge the second and the fourth capacitor;
operate the second charging circuit to charge the third and the fourth capacitor;
maintain the first and the second capacitor void of charge;
operate the first driver to discharge the first and the third capacitor; and
operate the second driver to discharge the second and the fourth capacitor.

2. The sub-system of claim 1, wherein the LiDAR system includes an electric circuit, the electric circuit being configured to coordinate operations of the first and the second drivers of the sub-system with operations of drivers of other sub-systems of the LIDAR system.

3. The sub-system of claim 1, wherein the LIDAR system includes one or more other sub-systems.

4. The sub-system of claim 1, wherein
the first driver is configured to remove the first charge from the first capacitor through the first LED by engaging a first switch,
the first driver is configured to remove the third charge from the third capacitor through the third LED by engaging a third switch,
the second driver is configured to remove the second charge from the second capacitor through the second LED by engaging a second switch, and
the second driver is configured to remove the fourth charge from the fourth capacitor through the fourth LED by engaging a fourth switch.

5. The sub-system of claim 1, wherein the first LED is adjacent to the third LED and the second LED is adjacent to the fourth LED.

6. The sub-system of claim 1, wherein each LED is a vertical cavity surface emitting laser diode or an edge emitting laser diode.

7. The sub-system of claim 4, wherein each switch is a gallium nitride filed effect transistor.

8. A method to operate a sub-system of a light detection and ranging (LiDAR) system, the sub-system includes:
a first capacitor, a second capacitor, a third capacitor, a fourth capacitor;
a first light emitting diode (LED), a second LED, a third LED, a fourth LED;
a first driver configured to discharge the first capacitor and the third capacitor through the first LED and the third LED respectively; and
a second driver configured to discharge the second capacitor and the fourth capacitor through the second LED and the fourth LED respectively;
the method comprising:
operating a first charging circuit to place a first and a second charge to the first and the second capacitor respectively;
maintaining the third and the fourth capacitor void of charge;
operating the first driver to discharge the first and the third capacitor through the first LED and the third LED respectively, thereby moving the first charge through the first LED and causing only the first LED to emit light;
operating the second driver to discharge the second and the fourth capacitor through the second LED and the fourth LED respectively, thereby moving the second charge through the second LED and causing only the second LED to emit light;
maintaining the first and the second capacitor void of charge;
operating a second charging circuit to place a third and a fourth charge to the third and the fourth capacitor respectively;
operating the first driver to discharge the first and the third capacitor through the first LED and the third LED respectively, thereby moving the third charge through the third LED and causing only the third LED to emit light; and
operating the second driver to discharge the second and the fourth capacitor through the second LED and the fourth LED respectively, thereby moving the fourth charge through the fourth LED and causing only the fourth LED to emit light.

9. The method of claim 8 further comprising:
coordinating operations of the first and the second driver with operations of other drivers of the LiDAR system.

10. The method of claim 9, wherein the other drivers of the LiDAR system include one or more pairs of drivers.

11. The method of claim 8, wherein
the first driver removes the first charge from the first capacitor through the first LED by engaging a first switch,
the first driver removes the third charge from the third capacitor through the third LED by engaging a third switch,
the second driver removes the second charge from the second capacitor through the second LED by engaging a second switch, and
the second driver removes the fourth charge from the fourth capacitor through the fourth LED by engaging a fourth switch.

12. The method of claim 8, wherein the first LED is adjacent to the third LED and the second LED is adjacent to the fourth LED.

13. The method of claim 8, wherein each LED being a vertical cavity surface emitting laser diode or an edge emitting laser diode.

14. The method of claim 8,
wherein the first and the second charging circuit being operated during a first period of time and a second period of time respectively,
wherein a value of the first charge and a value of the second charge being defined by the first period of time, and
wherein a value of the third charge and a value of the fourth charge being defined by the second period of time.

15. A light detection and ranging (LiDAR) system comprising:
an emitting unit configured to emit a light onto surrounding objects, the emitting unit includes a sub-system; and
a receiving unit configured to detect a portion of the light reflected from the surrounding objects;
the sub-system includes:
a first capacitor, a second capacitor, a first charging circuit configured to place a first charge and a second charge into the first and the second capacitor respectively;
a third capacitor, a fourth capacitor, a second charging circuit configured to place a third charge and a fourth charge into the third and the fourth capacitor respectively;
a first light emitting diode (LED), a second LED, a third LED, a fourth LED;
a first driver configured to remove the first charge from the first capacitor through the first LED and the third charge from the third capacitor through the third LED; and
a second driver configured to remove the second charge from the second capacitor through the second LED and the fourth charge from the fourth capacitor through the fourth LED, moving the first, the second, the third, and the fourth charge through a respective LED causes the respective LED to emit light;
the sub-system being configured to:
operate the first charging circuit to charge the first and the second capacitor;
maintain the third and the fourth capacitor void of charge;
operate the first driver to discharge the first and the third capacitor;
operate the second driver to discharge the second and the fourth capacitor;
operate the second charging circuit to charge the third and the fourth capacitor;
maintain the first and the second capacitor void of charge;
operate the first driver to discharge the first and the third capacitor; and
operate the second driver to discharge the second and the fourth capacitor.

16. The LiDAR system of claim 15 further comprising an electric circuit, the electric circuit being configured to coordinate operations of the first and the second drivers of the sub-system with operations of drivers of other sub-systems of the LIDAR system.

17. The LiDAR system of claim 15, wherein the emitting unit includes one or more other sub-systems.

18. The LiDAR system of claim 15, wherein
the first driver is configured to remove the first charge from the first capacitor through the first LED by engaging a first switch,
the first driver is configured to remove the third charge from the third capacitor through the third LED by engaging a third switch,
the second driver is configured to remove the second charge from the second capacitor through the second LED by engaging a second switch, and
the second driver is configured to remove the fourth charge from the fourth capacitor through the fourth LED by engaging a fourth switch.

19. The LiDAR system of claim 15, wherein the first LED is adjacent to the third LED and the second LED is adjacent to the fourth LED.

20. The LiDAR system of claim 15, wherein each LED is a vertical cavity surface emitting laser diode or an edge emitting laser diode.
